(19) United States
(12) Patent Application Publication
(10) Pub. No.: US 2006/0128162 A1
(43) Pub. Date: Jun. 15, 2006

(54) Process for fabricating a semiconductor device having an RTCVD layer

(76) Inventors: Sunil D. Mehta, San Jose, CA (US); Steven J. Fong, San Jose, CA (US); YongZhong Hu, Cupertino, CA (US)

Correspondence Address: LATTICE SEMICONDUCTOR CORPORATION, 5555 NE MOORE COURT, HILLSBORO, OR, 97124-6421, US

(21) Appl. No.: 11/013,240

(22) Filed: Dec. 14, 2004

(51) Int. Cl. H01L 21/31

(52) U.S. Cl. 438/778

(57) ABSTRACT

A process of fabricating a semiconductor device includes forming a device region including a non-volatile memory element and forming a utility layer overlying the device region, where the utility layer is a dielectric material formed by RTCVD. The utility layer preferably has a hydrogen content below that necessary to reduce the data retention of the non-volatile memory element in the device region. The utility layer can function as one or more of an etch-stop layer, a diffusion barrier layer, or an insulating layer.

### TECHNICAL FIELD

This invention relates, generally, to semiconductor device fabrication and, more particularly, to the fabrication of dielectric layers overlying charge storage elements in nonvolatile memory devices, such as erasable-read-only memory (EPROM) and electrically- erasable-read-only memory (EEPROM) devices, and the like.

### BACKGROUND

Modern nonvolatile memory arrays such as EPROMs, Flash EPROMs, and EEPROMs, include charge storage devices that store electrical charge within charge storage elements in the array. The presence or absence of charge on the storage elements determines the logic state for the memory cell, usually designated by a binary code of 0 or 1. The fabrication of these nonvolatile memory devices typically includes the formation of several dielectric layers overlying the charge storage device. In state of the art devices, in to addition electrical isolation layers, a diffusion barrier layer and etch stop layer are applied over the charge storage elements.

In some cases, the memory performance of the nonvolatile arrays can be compromised by chemical constituents of the dielectric and isolation layers. In particular, hydrogen contained within deposited silicon nitride has been shown to diffuse into floating-gates within nonvolatile memory devices and compromise the charge state of the memory cell. For example, high temperature data retention failure has been observed in memory. devices fabricated with silicon nitride layers overlying the floating-gate electrodes. The poor high-temperature data retention may be due to mobile hydrogen atoms that diffuse to the floating-gate in a nonvolatile memory cell and cause the charge on the floating-gate to be lost. One measure of data retention is the charge loss (ΔVt) measured after baking the devices at an elevated temperature for an extended time. The typical standard for the maximum acceptable charge loss is about 0.1V over a bake period of about 24 hours. The charge loss observed in EEPROM devices that have silicon nitride etch stop layers, for example, is well above the 0.1V acceptable upper limit.

Several commonly-used silicon nitride deposition techniques have been found to deposit silicon nitride having a large hydrogen content. For example, plasma-enhanced-chemical-vapor-deposition (PECVD) is widely known to produce high hydrogen content silicon nitride. Although increasing the PECVD deposition temperature reduces the hydrogen content of the deposited film, operation of PECVD equipment above 480° C. is difficult. Another common silicon nitride deposition technique involves low-pressure-chemical-vapor-deposition (LPCVD). The temperature of this process can be relatively high, for example in the range of about 800° C. Although this high temperature deposition method removes free hydrogen from the deposited silicon nitride layer, LPCVD places large stresses on the deposited layer and underlying device structure.

Accordingly, a need existed for a fabrication method capable of forming a dielectric layer having low hydrogen content and that is compatible with the requirements for high-density memory devices.

### SUMMARY

In accordance with one embodiment of the invention, a process for fabricating a semiconductor device includes forming a device region including a non-volatile memory element, and forming a utility layer overlying the device region. The utility layer is a dielectric material, such as silicon nitride, and the like, that is formed by rapid-thermal-chemical-vapor-deposition (RTCVD).

In another embodiment of the invention, a process for fabricating a memory device includes forming a data storage element having a predetermined data retention. A utility layer is formed by RTCVD to overlie the storage layer. The utility layer has a hydrogen content below that necessary to reduce the predetermined data retention of the data storage element.

In yet another embodiment of the invention, a process for fabricating a memory device includes forming a memory element having a predetermined data retention level. An RTCVD process is carried out to deposit an etch-stop layer overlying the memory element. An insulating layer is formed to overlie the etch-stop layer, such that the predetermined data retention level of the memory element remains substantially unchanged. Contact openings are formed in the insulating layer and the etch-stop layer, and the openings are filled with a contact material.

In still another embodiment of the invention, a process for fabricating an etch-stop layer in a semiconductor device includes forming a charge storage element and forming an etch-stop layer overlying the charge storage element. The etch-stop layer is formed by RTCVD of a material comprising silicon nitride.

### BRIEF DESCRIPTION OF THE DRAWING

FIG. 1 is a cross-sectional view of a memory element having a utility layer formed in accordance with one embodiment of the invention;

FIG. 2 is a cross-sectional view of a stacked-gate memory element having a utility layer formed in accordance with another embodiment of the invention;

FIGS. 3-5 are cross-sectional views of a memory fabrication process in accordance with an embodiment of the invention; and

FIG. 6 is a histogram illustrating data retention values for memory elements fabricated in accordance with the embodiments of the invention and in accordance with the prior art.

It will be appreciated that for simplicity and clarity of illustration, some elements have been exaggerated relative to others. Further, where considered appropriate, reference numerals have been repeated among the Figures to indicate corresponding elements.

### DETAILED DESCRIPTION

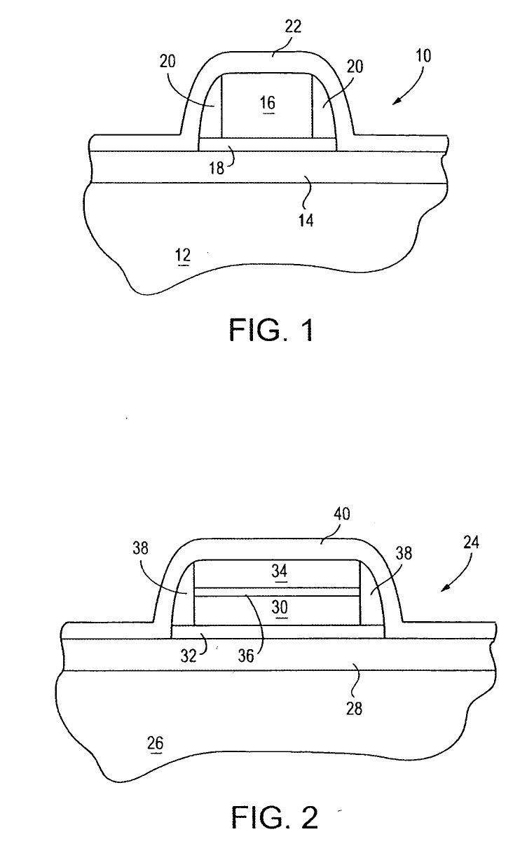

Shown in FIG. 1, in cross-section, is a portion of a semiconductor device 10 having already undergone several processing steps in accordance with an embodiment of the invention. A semiconductor substrate 12 includes a charge transfer region 14. A floating-gate electrode 16 overlies charge transfer region 14 and is separated therefrom by a tunnel dielectric layer 18. Sidewall spacers 20 reside adjacent to the sidewalls of floating-gate electrode 16. A utility layer 22 overlies floating-gate electrode 16, sidewall spacers 20, and additional portions of substrate 12.

In operation, voltages are applied to charge transfer region 14 and floating-gate electrode 16 that cause electrical charge to be transferred from charge transfer region 14 across tunnel dielectric layer 18 and onto floating-gate electrode 16. In accordance with one embodiment of the invention, where the elements illustrated in FIG. 1 are component parts of a memory device, such as an EEPROM device, the charge stored on floating-gate electrode 16 will remain on the electrode until such time as erase voltages are applied to charge-transfer region 14 and floating-gate electrode 16. At that time, the charge will be dissipated from floating-gate electrode 16.

According to the operational method described above, data in the form of electrical charge can be stored on floating-gate electrode 16. Under ideal circumstances, the data, in the form of electrical charge, will remain undisturbed on floating-gate electrode 16 for a prolonged period of time. The ability to maintain the electrical charge on floating-gate electrode 16 is known in the art as “data retention.” Under ideal circumstances, floating-gate electrode 16 will have perfect data retention and will not lose electrical charge once it is transferred to floating-gate electrode 16.

In order to maintain acceptable data retention levels, utility layer 22 is preferably formed by a process that forms the utility layer to have a relatively low hydrogen content. Preferably, the hydrogen content is below that necessary to substantially reduce the predetermined data retention level of floating-gate electrode 16. Further, in accordance with an embodiment of the invention, utility layer 22 is formed at a temperature that does not interfere with other components of an EEPROM device.

In order to maintain high data retention levels and process compatibility in a memory device fabrication process, utility layer 22 is preferably formed by an RTCVD process. In an embodiment of the invention, where utility layer 22 is a silicon nitride material, the RTCVD process deposits a layer of silicon nitride at a temperature of about 500° C. to about 550° C. Those skilled in the art will appreciate that the deposition of silicon nitride in an RTCVD system can be carried out in a single-wafer deposition process in a relatively short period of time. Since the RTCVD process is carried out on a single wafer, the temperature to which the substrate is subjected can be controlled to minimize hydrogen incorporation into the silicon nitride material. Further, the precise temperature control also permits a silicon nitride film to be deposited having relatively low film stress. The relatively low deposition temperature avoids undesirable diffusion of impurities previously introduced into various layers within the EEPROM device. Further, previously formed alloys, such as refractory metal silicide, and the like, are not degraded during the RTCVD process.

In accordance with the invention where utility layer 22 is intended to be an etch-stop layer, utility layer 22 is deposited to have a thickness of about 500 angstroms to about 1000 angstroms. In an alternative embodiment of the invention, where utility layer 22 is intended to be a diffusion barrier layer, utility layer 22 is deposited to a thickness of about 400 angstroms to about 700 angstroms. Further, the hydrogen content of the RTCVD silicon nitride material is preferably less than about 7 wt. % and, more preferably, less than about 3.5 wt. %.

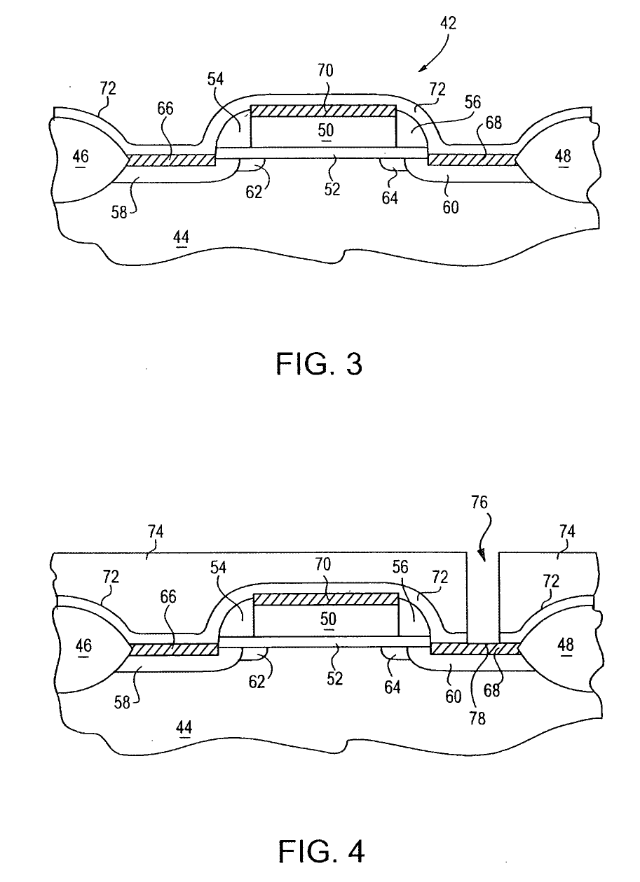

FIG. 2 illustrates cross-section, a semiconductor device 24 fabricated in accordance with another embodiment of the invention. Semiconductor device 24 includes a substrate 26 having a charge transfer layer 28 and a floating-gate electrode 30 overlying charge-transfer layer 28 and separated therefrom by a tunnel dielectric layer 32. A control-gate electrode 34 overlies floating-gate electrode 30 and is separated therefrom by a capacitor dielectric layer 36. Sidewall spacers 38 reside adjacent to the sidewalls of control-gate electrode 34 and floating-gate electrode 30. A utility layer 40 overlies control-gate electrode 34 and sidewall spacers 38, and remaining portions of substrate 26.

The memory element illustrated in FIG. 2 is a stacked-gate memory device in which charge is transferred from charge transfer layer 28 to floating-gate electrode 30 by a potential (V_{CG}) that is capacitively coupled from control-gate 34 to floating-gate 30.

Utility layer 40 is preferably formed by a known RTCVD process and can either be an etch-stop layer, a diffusion barrier layer, or other insulating layer having a predetermined function. In similarity with the embodiment described above, utility layer 40 is formed in a manner that does not substantially reduce the data retention of the underlying memory element.

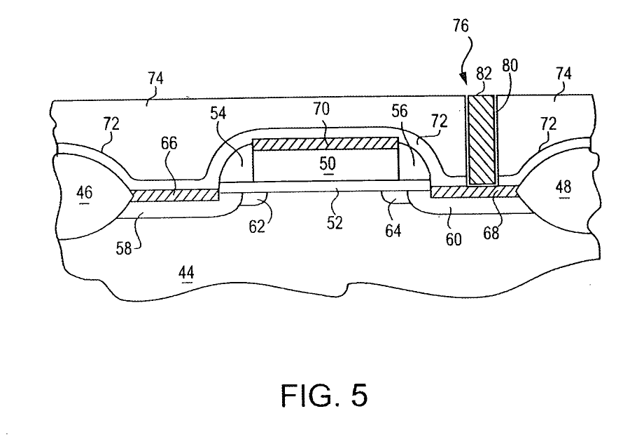

In another embodiment of the invention, a utility layer formed by an RTCVD process is used in a contact formation process. FIGS. 3-5 illustrate, in cross-section, processing steps for the fabrication of an electrical contact to a refractory silicide layer. Referring to FIG. 3, a memory element 42 is illustrated. having already undergone several processing steps in accordance with an embodiment of the invention. A semiconductor substrate 44 includes field oxide regions 46 and 48. A gate electrode 50 overlies semiconductor substrate 44 and is separated therefrom by a gate dielectric layer 52. Sidewall spacers 54 and 56 reside on either side of gate electrode 50. Source and drain regions 58 and 60, respectively, reside in semiconductor substrate 44 on either side of gate electrode 50. Also, source and drain extension regions 62 and 64 reside adjacent to source and drain regions 58 and 60, respectively. Further, refractory metal silicide regions are formed in the surface of semiconductor substrate 44 at source and drain regions 58 and 60 and in the upper surface of gate electrode 50. In particular, a refractory metal silicide region 66 resides in the surface of semiconductor substrate 44 above source region 58, and refractory metal silicide region 68 resides in the surface of semiconductor substrate 44 above drain region 60. Also, a refractory metal silicide region 70 resides in the upper surface of gate electrode 50.

In accordance with an embodiment of the invention, a utility layer 72 is formed by RTCVD to overlie the refractory metal silicide layers, the sidewall spacers, and the field oxide regions of memory element 42. Utility layer 72 functions as either a diffusion barrier layer or an etch-stop layer. Utility layer 72 protects the underlying components of memory element 42 from processing-related defects, such as diffusion of global species, such as sodium, potassium, and the like, or functions to protect underlying layers from undesired attack by etchings used in subsequent etching attacks. Preferably, utility layer 72 is fabricated using RTCVD processing conditions described above.

Those skilled in the art will recognize that the structure illustrated in FIG. 3 can be fabricated with various materials. For example, field oxide regions 46 and 48 can be isolations structures, such as shallow trench isolation structures (STI), and the like. Further, gate dielectric layer 52 can be one of many different known gate dielectric materials, such as silicon oxide, silicon nitride, silicon oxynitride, and the like. Further, the transistor structure illustrated in FIG. 3 can be either an n-type device or a p-type device. Further, gate electrode 50 can be polycrystalline silicon, amorphous silicon, and the like. Also, the refractory metal suicide layers can be any of a number of different known refractory metal silicides, such as cobalt silicide, titanium silicide, and the like.

Once utility layer 72 is deposited, memory element 42 can be optionally subjected to a thermal annealing process. The thermal annealing process functions to drive off any excess hydrogen present in utility layer 72. After forming utility layer 72, as illustrated in FIG. 4, a relatively thick insulating layer 74 is deposited over memory element 42 and a contact opening 76 is formed to expose a portion of 78 of refractory metal silicide layer 68. In the illustrated embodiment, utility layer 72 functions to prevent contamination of underlying structures during the deposition, planarization, and etching processes carried out on insulating layer 74.

Referring to FIG. 5, after forming contact opening 76, an adhesive layer 80 is formed to line the sidewalls of contact opening 76 and to overlie portion 78 of refractory metal silicide layer 68. Preferably, adhesive layer 80 is an refractory metal, such as titanium, and the like, or a refractory metal compound, such as titanium nitride. Adhesive layer 80 is preferably formed by conformally depositing a layer of adhesive material, and subsequently, removing the adhesive material from the upper surface of insulating layer 74.

After forming adhesive layer 80, a contact material 82 is formed to fill contact opening 76. Preferably, contact material 82 is a refractory metal, such as tungsten, and the like. After depositing contact material 82, a planarization process is carried out to remove portions of the contact material overlying the surface of insulating layer 74. Utility layer 72 continues to function as a barrier layer to minimize contamination of underlying structures during the final phases of contact formation.

Those skilled in the art will appreciate that the contact formation process described above is one of many different such processes. For example, numerous types of electrical contacts are routinely made during a semiconductor fabrication process. For example, in multi-level metal devices, several overlying insulating and metal layers are formed and interconnected through via openings in the insulating layers. Further, contact openings can also be made to gate electrodes, such as gate electrode 50.

### EXAMPLE

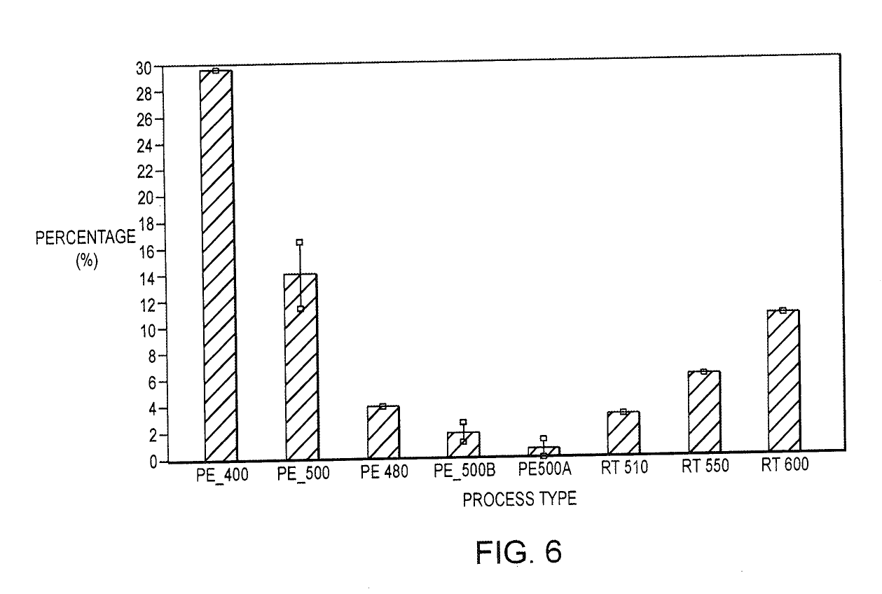

A comparative analysis of the data retention characteristics of devices fabricated with a utility layer in accordance with an embodiment of the invention versus memory devices having a similar layer fabricated in accordance with the prior art is illustrated in FIG. 6. In the histogram of FIG. 6, the percentage of test devices having a threshold voltage shift between 0.1 volts and 0.3 volts is plotted for several different processing conditions. To determine the affect on data retention, silicon nitride layers were deposited using either a known PECVD deposition process or an RTCVD process carried out in accordance with an embodiment of the invention. The samples identified as “PE” were prepared by depositing a silicon nitride layer in a PECVD apparatus having at a deposition temperature ranging from 400° C. to 500° C., while the RTCVD silicon nitride layers were deposited at a deposition temperature ranging from about 510° C. to 600° C.

The test samples identified with the suffix “A” and “B” are similar structures fabricated having PECVD layers deposited at 500° C. that were prepared in difference processing equipment. The test devices fabricated in accordance with an embodiment of the invention are denoted by the prefix “RT.”

The test devices were standardized test structures having metal-oxide-silicon (MOS) transistor devices fabricated in a single crystal silicon substrate. After fabricating the transistors, a silicon nitride layer having a thickness of about 600 angstroms was deposited to overlie the MOS transistors.

To determine the data retention capability, the threshold voltage of the MOS transistors was measured on fully processed devices after programming. The test samples were also subjected to thermal annealing at a temperature of about 250° C. for about 24 hours. After annealing, the threshold voltage of the MOS transistors was again measured and compared with the initially measured threshold voltage values. The percentage of test structures having a change in threshold voltage between 0.1 volts and 0.3 was calculated to obtain the plot illustrated in FIG. 6.

The data shown in FIG. 6 indicates that the sample having silicon nitride layers formed by an RTCVD process compared favorably with samples having silicon nitride layers a PECVD process. The histogram indicates that samples deposited by RTCVD at a temperature of 510° C. have slightly better data retention than samples having silicon nitride layers fabricated at temperatures of 550° C. and 600° C.

Thus, it is apparent that there has been described, in accordance with the various embodiments of the invention, a process for fabricating a semiconductor device having an RTCVD layer that fully provides the advantages set forth above. Although the invention has been described and illustrated with reference to specific illustrative embodiments thereof, it is not intended that the invention be limited to those illustrative embodiments. Those skilled in the art will recognize that variations and modifications can be made without departing from the spirit of the invention. For example, although memory elements are described having data storage elements illustrated in the form of gate electrode structures, other charge non-volatile storage elements, such as substrate regions, and various conductive, semiconductive, and dielectric layers can also be device regions that function as a data storage element, a non-volatile memory element, a charge storage element, and the like. It is therefore intended to include within the invention, all such variations and modifications as fall within the scope of the appended claims and equivalents thereof.

1. A process of fabricating a semiconductor device comprising:
forming a device region including a non-volatile memory element;
forming a utility layer overlying the device region,
wherein the utility layer comprises a silicon nitride material formed by RTCVD.

2. The process of claim 1, wherein forming a utility layer comprises forming a layer having a hydrogen content below that necessary to reduce the predetermined data retention of the data storage element.

3. The process of claim 1, wherein forming a device region comprises forming one of an MOS gate electrode or a floating-gate electrode.

4. The process of claim 1, wherein forming the utility layer comprises forming an etch-stop layer.

5. The process of claim 1, wherein forming the utility layer comprises forming a barrier layer.

6. The process of claim 1, wherein the RTCVD is carried out at a temperature of about 500° C. to about 550° C.

7. A process for fabricating a memory device comprising:
forming a data storage element having a predetermined data retention; and
forming a utility layer by RTCVD overlying the storage layer,
wherein the utility layer has a hydrogen content below that necessary to reduce the predetermined data retention of the data storage element.

8. The process of claim 7, wherein forming the utility layer comprises forming an etch-stop layer.

9. The process of claim 7, wherein forming the utility layer comprises forming a barrier layer.

10. The process of claim 7, wherein forming the utility layer comprises forming a silicon nitride layer.

11. A process for fabricating a memory device comprising:
forming a memory element having a predetermined data retention level;
carrying out an RTCVD process to deposit an etch-stop layer overlying the memory element;
forming an insulating layer overlying the etch-stop layer, such that the predetermined data retention level of the memory element remains substantially unchanged;
forming contact openings in the insulating layer and the etch-stop layer; and
filling the openings with a contact material.

12. The process of claim 11, wherein carrying out an RTCVD process comprises heating the memory element to a temperature of about 500° C. to about 550° C.

13. The process of claim 11, wherein the etch-stop layer comprises a layer having a sufficiently low hydrogen content to maintain the predetermined data retention level of the memory element.

14. The process of claim 11, wherein forming a memory element comprises forming a floating-gate layer overlying a substrate and capacitvely coupled to a control region in the substrate.

15. The process of claim 11, wherein forming a memory element comprises forming a floating-gate layer capacitvely coupled to a control-gate layer overlying the floating-gate layer and separated therefrom by a capacitor dielectric layer.

16. A process of fabricating an etch-stop layer in a semiconductor device comprising:
forming a charge storage element; and
forming an etch-stop layer overlying the charge storage element by RTCVD of a material comprising silicon nitride.

17. The process of claim 16, wherein charge storage element comprises forming a floating-gate electrode.

18. The process of claim 16, wherein forming an etch-stop layer overlying the charge storage element by RTCVD of silicon nitride comprises carrying out an RTCVD process at a temperature of about 500° C. to about 550° C.

19. The process of claim 16, wherein the charge storage element is fabricated to have a redetermined data retention, and wherein forming an etch-stop layer comprises forming a layer having a hydrogen content below that necessary to substantially reduce the predetermined data retention of the charge storage element.

20. The process of claim 19 further comprising:
forming an insulating layer overlying the etch-stop layer, such that the predetermined data retention level of the charge storage element remains substantially unchanged;
forming contact openings in the insulating layer and the etch-stop layer; and
filling the openings with a contact material.
